(19) United States
(12) Patent Application Publication
(10) Pub. No.: US 2016/0379937 A1
(43) Pub. Date: Dec. 29, 2016

(54) SUBSTRATE STRIP

(71) Applicant: Samsung Electronics Co., Ltd., Suwon-si (KR)

(72) Inventors: KyongSoon CHO, Incheon (KR); Myoungkyun KIL, Seoul (KR); Hansung RYU, Seoul (KR)

(21) Appl. No.: 15/138,441

(22) Filed: Apr. 26, 2016

(30) Foreign Application Priority Data
Jun. 23, 2015 (KR) 10-2015-0089222

(51) Int. Cl. H01L 23/00; H05K 1/11; H05K 1/02; H01L 23/498

(52) U.S. Cl. CPC H01L 23/562; H01L 23/49822; H01L 23/49838; H05K 1/111; H05K 1/0298; H05K 1/0271

(57) ABSTRACT

A substrate strip is provided. The substrate strip includes a core layer including first and second substrate regions spaced apart from each other and a dummy region between the first and second substrate regions, a first interconnection layer disposed on top surfaces of the first and second substrate regions, a second interconnection layer disposed on bottom surfaces of the first and second substrate regions, and a warpage control member provided on any one of a top surface and a bottom surface of the dummy region. The warpage control member includes a metal.

### CROSS-REFERENCE TO RELATED APPLICATION

This patent application claims priority under 35 U.S.C. §119 to Korean Patent Application No. 10-2015-0089222, filed on Jun. 23, 2015, in the Korean intellectual Property Office, the disclosure of which is hereby incorporated by reference in its entirety.

### BACKGROUND

Example embodiments of the inventive concepts relate to a substrate strip and, more particularly, to a substrate strip including a warpage control member formed on one surface of a dummy region.

As sizes of electronic products have been reduced, small and slim printed circuit package substrates have also been demanded. On the other hand, as integration densities of electronic products have been increased, a relative area where a semiconductor chip occupies has been increased in a package substrate. As a package substrate has been thinned and a package product has been compacted, a warpage problem of a substrate strip may occur.

### SUMMARY

Embodiments of the inventive concepts may provide a substrate strip capable of reducing or minimizing a warpage phenomenon.

In one aspect, a substrate strip may include a core layer including first and second substrate regions spaced apart from each other and a dummy region between the first and second substrate regions, a first interconnection layer disposed on first surfaces of the first and second substrate regions, a second interconnection layer disposed on second surfaces opposite to the first surfaces of the first and second substrate regions, and a warpage control member provided on any one of a first surface and a second surface of the dummy region. The warpage control member may include a metal.

In some embodiments, the warpage control member may include copper.

In some example embodiments, the warpage control member may be in contact with the core layer.

In some example embodiments, the warpage control member may be electrically insulated from the first and second interconnection layers.

In some example embodiments, the warpage control member may include the same material as the first interconnection layer or the second interconnection layer.

In some example embodiments, the warpage control member may be provided on the second surface of the dummy region, and the warpage control member may be disposed at the same level as the second interconnection layer, relative to the core layer.

In some example embodiments, the core layer may have a long axis extending in a first direction. The first and second substrate regions may be spaced apart from each other in the first direction, and the dummy region may extend in a second direction intersecting the first direction.

In some example embodiments, the warpage control member may have a rectangular shape extending in the second direction when viewed in plan view.

In some example embodiments, the warpage control member may include segments spaced apart from each other and repeatedly arranged in the second direction when viewed in plan view.

In some example embodiments, the substrate strip may further include a third interconnection layer disposed between the core layer and the second interconnection layer, and a fourth interconnection layer disposed between the core layer and the first interconnection layer.

In some example embodiments, the warpage control member may be disposed at the same level as one of the first to fourth interconnection layers, relative the core layer.

In some example embodiments, the warpage control member may include a first warpage control member and a second warpage control member. The first warpage control member may be disposed at the same level as the second interconnection layer, based on the core layer, and the second warpage control member may be disposed at the same level as the third interconnection layer, relative to the core layer.

In another aspect, a substrate strip may include a core layer including first and second substrate regions spaced apart from each other and a dummy region surrounding the first and second substrate regions, a first interconnection layer disposed on top surfaces of the first and second substrate regions, a second interconnection layer disposed on bottom surfaces of the first and second substrate regions, a warpage control member disposed on a bottom surface of the dummy region, a first solder resist layer covering the first interconnection layer, and a second solder resist layer covering the second interconnection layer and the warpage control member.

In some example embodiments, the warpage control member may have a coefficient of thermal expansion (CTE) greater than that of the core layer.

In some example embodiments, the warpage control member may include a metal.

In some example embodiments, the warpage control member may be disposed directly on the bottom surface of the dummy region.

In some example embodiments, the warpage control member may include the same material as the second interconnection layer.

In some example embodiments, the warpage control member may be disposed at the same level as the second interconnection layer, based on the core layer.

In some example embodiments, the first interconnection layer may include a chip bonding pad, and the second interconnection layer may include an external connection pad.

In other aspect, a substrate strip may include a core layer including a first surface and a second surface that is opposite to the first surface, a first interconnection layer on the first surface of the core layer and including a first pad, a second interconnection layer on the second surface of the core layer and including a second pad, and a warpage control member on one of the first surface and the second surface of the core layer and being separated from the first interconnection layer and the second interconnection layer. The warpage control member may be disposed at a same level as the one of the first interconnection layer and the second interconnection layer, relative to the core layer, and is free of the first and second pads.

### BRIEF DESCRIPTION OF THE DRAWINGS

The inventive concepts will become more apparent in view of the attached drawings and accompanying detailed description.

FIGS. 1A and 1B are plan views illustrating substrate strips according to some example embodiments of the inventive concepts.

FIG. 2 is a cross-sectional view taken along a line I-I′ of FIG. 1A or 1B to illustrate a substrate strip according to an example embodiment of the inventive concepts.

FIG. 3 is a cross-sectional view illustrating a substrate strip, on which semiconductor chips are mounted, according to an example embodiment of the inventive concepts.

FIG. 4A is a cross-sectional view illustrating an example of a dummy region and a warpage control member deformed by a thermal process.

FIG. 4B is a cross-sectional view illustrating a total warpage degree of a substrate strip relaxed using the deformation of the dummy region and the warpage control member illustrated in FIG. 4A.

FIG. 5A is a cross-sectional view illustrating an example of a dummy region and a warpage control member deformed by a thermal process.

FIG. 5B is a cross-sectional view illustrating a total warpage degree of a substrate strip relaxed using the deformation of the dummy region and the warpage control member illustrated in FIG. 5A.

FIG. 6 is a cross-sectional view taken along the line I-I′ of FIG. 1A or 1B to illustrate a substrate strip according to an example embodiment of the inventive concepts.

FIG. 7 is a cross-sectional view taken along the line I-I′ of FIG. 1A or 1B to illustrate a substrate strip according to an example embodiment of the inventive concepts.

FIG. 8 is a schematic block diagram illustrating an example of an electronic system including a semiconductor package according to an example embodiment of the inventive concepts.

FIG. 9 is a schematic block diagram illustrating an example of a memory card including a semiconductor package according to an example embodiment of the inventive concepts.

### DESCRIPTION OF THE EMBODIMENTS

The inventive concepts will now be described more fully hereinafter with reference to the accompanying drawings, in which example embodiments of the inventive concepts are shown. The advantages and features of the inventive concepts and methods of achieving them will be apparent from the following example embodiments that will be described in more detail with reference to the accompanying drawings. It should be noted, however, that the inventive concepts are not limited to the following example embodiments, and may be implemented in various forms. Accordingly, the example embodiments are provided only to disclose the inventive concepts and let those skilled in the art know the category of the inventive concepts. In the drawings, embodiments of the inventive concepts are not limited to the specific examples provided herein and are exaggerated for clarity. The same reference numerals or the same reference designators denote the same elements throughout the specification.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, example embodiments are described herein with reference to cross-sectional views and/or plan views that are idealized example illustrations. Accordingly, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. Thus, the regions illustrated in the figures are schematic in nature and their shapes are not intended to limit the scope of example embodiments.

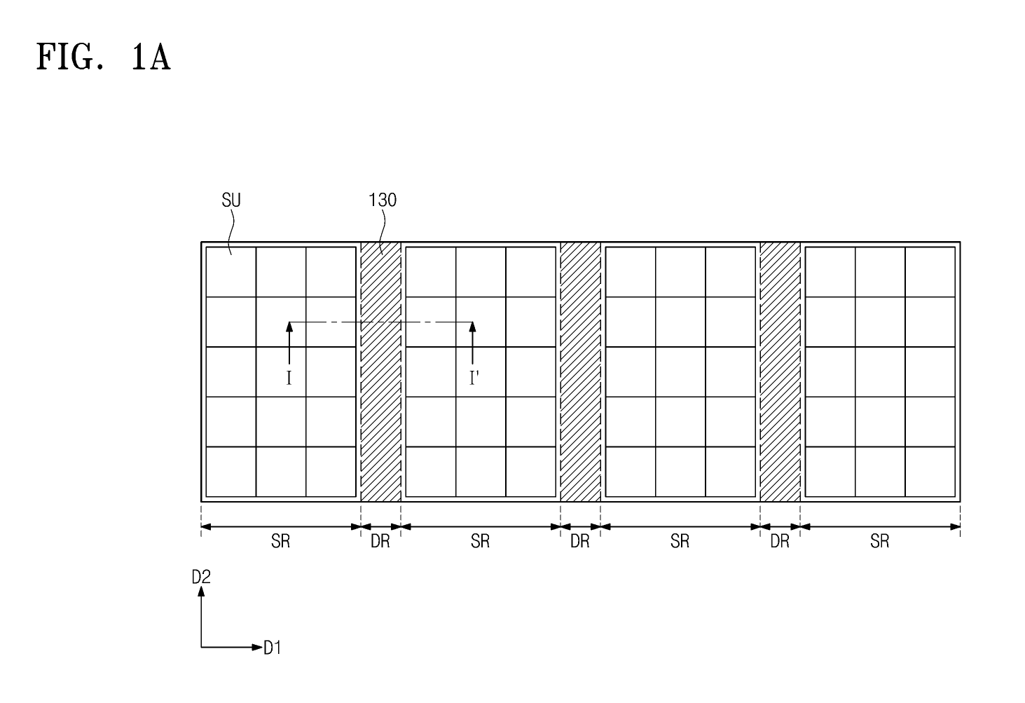

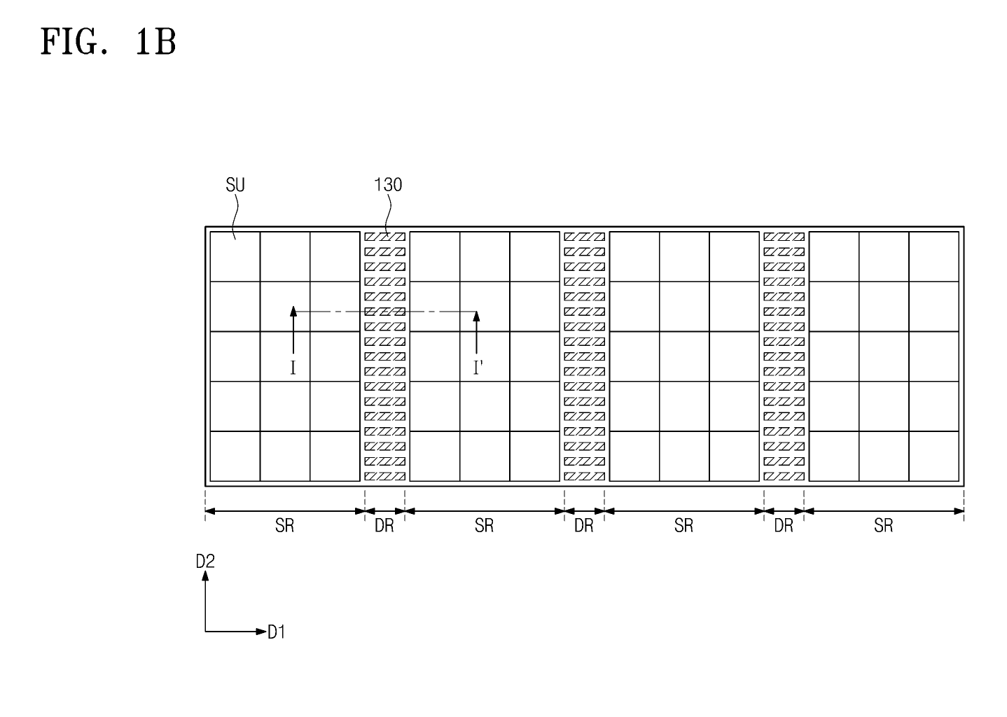

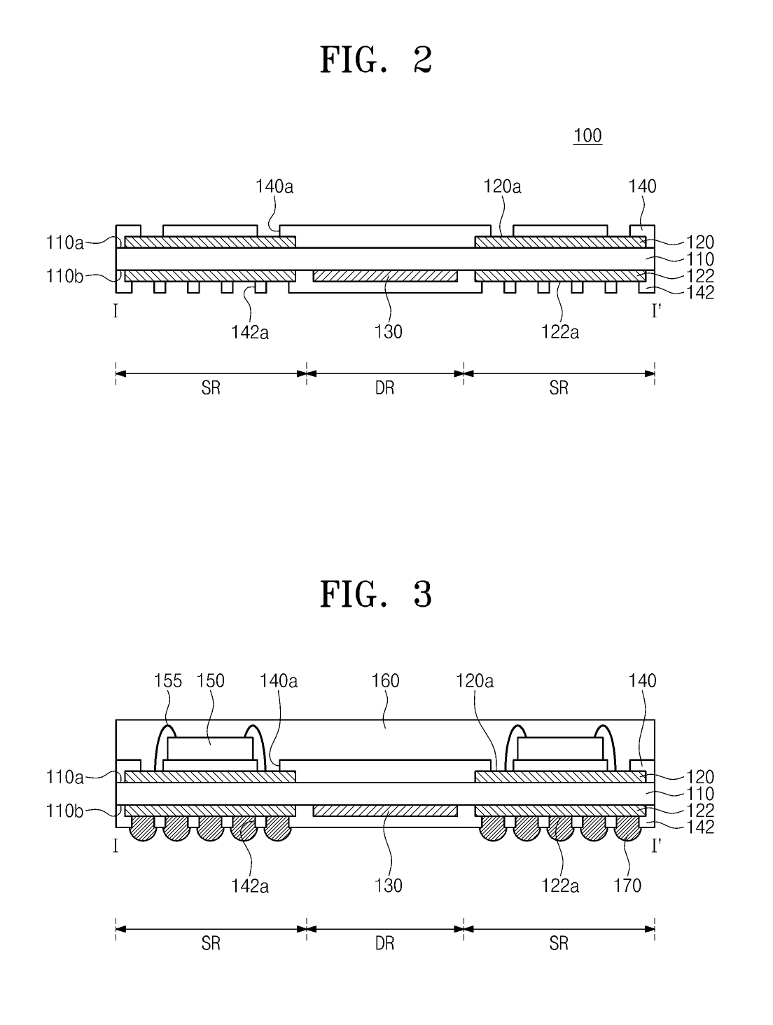

FIGS. 1A and 1B are plan views illustrating substrate strips according to some example embodiments of the inventive concepts. FIG. 2 is a cross-sectional view taken along a line I-I′ of FIG. 1A or 1B to illustrate a substrate strip according to an example embodiment of the inventive concepts.

Referring to FIGS. 1A, 1B, and 2, a substrate strip 100 may include a core layer 110, a first interconnection layer 120, a second interconnection layer 122, warpage control members 130, a first solder resist layer 140, and a second solder resist layer 142. The substrate strip 100 may serve as, for example, a package substrate for a semiconductor package. The core layer 110 may include a plurality of substrate regions SR and a plurality of dummy regions DR. The core layer 110 may include a top surface 110a and a bottom surface 110b opposite to the top surface 110a. The core layer 110 may have a long axis extending in a first direction D1. The core layer 110 may include an insulator. For example, the core layer 110 may include glass fiber, epoxy resin, bisphenol-A resin, epoxy-novolac resin, or reinforced epoxy resin.

The substrate regions SR may be spaced apart from each other in the first direction D1 with each of the dummy regions DR interposed therebetween. In an embodiment, the substrate regions SR and the dummy regions DR may be alternately arranged along the first direction D1. Each of the substrate regions SR may include a plurality of substrate units SU. Each of the substrate units SU may be a region on which a unit semiconductor chip is mounted. Thus, the interconnection layers 120 and 122 may be disposed on top and bottom surfaces 110a. and 110b of the substrate regions SR (e.g., the top and bottom surfaces 110a and 110b of the core layer 110 in the substrate regions SR), as described below.

Each of the dummy regions DR may be disposed between the substrate regions SR and may correspond to a region on which a semiconductor chip (not shown) is not mounted. Each of the dummy regions DR may extend in a second direction D2 intersecting the first direction D1.

The first interconnection layer 120 may be disposed on the top surfaces 110a of the substrate regions SR, and the second interconnection layer 122 may be disposed on the bottom surfaces 110b of the substrate regions SR. The first and second interconnection layers 120 and 122 may be electrically connected to each other through vias (not shown) penetrating the core layer 110. The first and second interconnection layers 120 and 122 may include a conductive metal. For example, the first and second interconnection layers 120 and 122 may include copper (Cu).

The first interconnection layer 120 may include chip bonding pads 120a. The semiconductor chip (not shown) may be electrically connected to the first interconnection layer 120 through the chip bonding pads 120a.

The second interconnection layer 122 may include external connection pads 122a. Solder balls (not shown) may be formed on the external connection pads 122a.

The warpage control members 130 may be disposed on top surfaces 110a or bottom surfaces 110b of the dummy regions DR (e.g., the top surfaces 110a or bottom surfaces 110b of the core layer 110 in the dummy regions DR). In some embodiments, as illustrated in FIG. 2, the warpage control members 130 may be disposed on the bottom surfaces 110b of the dummy regions DR. However, the inventive concepts are not limited thereto. In other embodiments, the warpage control members 130 may be disposed on the top surfaces 110a of the dummy regions DR. Hereinafter, the warpage control members 130 disposed on the bottom surfaces 110b of the dummy regions DR will be described as an example for the purpose of ease and convenience in explanation.

One warpage control member 130 may be disposed on one dummy region DR. Each of the warpage control members 130 may extend in the second direction D2. As illustrated in FIG. 1A, each of the warpage control members 130 may have a rectangular shape extending in the second direction D2 when viewed in plan view. However, the inventive concepts are not limited thereto. Alternatively, the warpage control members 130 may have regular patterns. In an embodiment, as illustrated in FIG. 1B, in plan view, each of the warpage control members 130 may have a striped pattern in which a plurality of segments are spaced apart from each other and are repeatedly arranged in the second direction D2. For example, each of the warpage control members 130 may include a plurality of segments that are spaced apart from each other and are repeatedly arranged in the second direction D2. The warpage control members 130 may be in contact with the bottom surface 110b of the core layer 110. In other words, the warpage control members 130 may be disposed directly on the bottom surface 110b of the core layer 110. The warpage control members 130 may be disposed at the same level as the second interconnection layer 122, relative to the core layer 110. The warpage control members 130 may be spaced apart from the first and second interconnection layers 120 and 122, so the warpage control members 130 may be electrically insulated from the first and second interconnection layers 120 and 122.

The warpage control members 130 may have a coefficient of thermal expansion (CTE) which is greater than that of the core layer 110. In an embodiment, the warpage control members 130 may include a metal such as copper.

According to some embodiments, the warpage control members 130 may be formed along with the second interconnection layer 122 during a process of forming the second interconnection layer 122. In such embodiments, forming the second interconnection layer 122 and the warpage control members 130 may include forming a conductive metal layer (not shown) on the bottom surface 110b of the core layer 110, and patterning the conductive metal layer. In such embodiments, the warpage control members 130 may include the same material as the second interconnection layer 122.

The first solder resist layer 140 may be disposed on the top surface 110a of the core layer 110 to cover the first interconnection layer 120 and top surfaces of the dummy regions DR. In some embodiments, as shown in FIG. 2, the first solder resist layer 140 may be in contact with the top surfaces of the dummy regions DR. The first solder resist layer 140 may include first openings 140a exposing the chip bonding pads 120a of the first interconnection layer 120.

The second solder resist layer 142 may be disposed on the bottom surface 110b of the core layer 110 to cover the second interconnection layer 122 and the warpage control members 130. The second solder resist layer 142 may include second openings 142a exposing the external connection pads 122a of the second interconnection layer 122.

FIG. 3 is a cross-sectional view illustrating a substrate strip, on which semiconductor chips are mounted, according to an example embodiment of the inventive concepts.

Referring to FIGS. 1A, 1B, 2, and 3, semiconductor chips 150, a molding layer 160, and external connection solder balls 170 may be further provided.

Each of the semiconductor chips 150 may be mounted on the substrate unit SU. The semiconductor chips 150 may be electrically connected to the first interconnection layer 120. In an embodiment, the semiconductor chips 150 may be electrically connected to the chip bonding pads 120a of the first interconnection layer 120 through bonding wires 155, as illustrated in FIG. 3. Alternatively, each of the semiconductor chips 150 may be mounted on the substrate unit SU by a flip chip bonding technique.

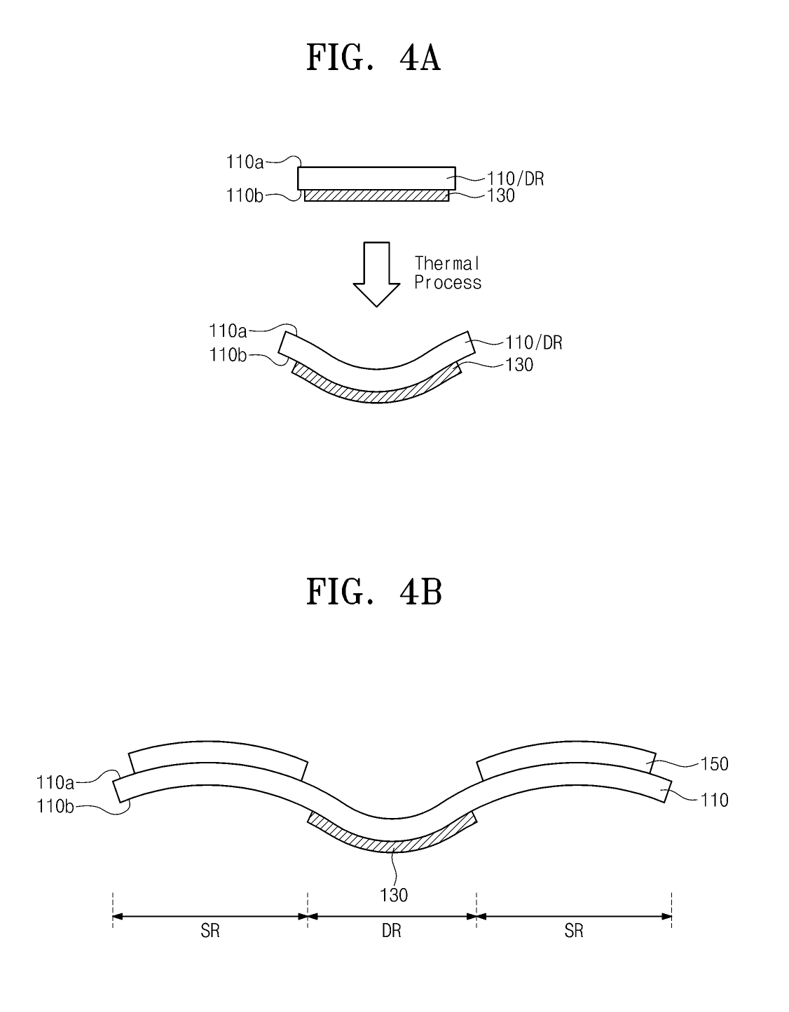

The semiconductor chips 150 may have a coefficient of thermal expansion (CTE) which is different from that of the core layer 110. In an embodiment, the CTE of the semiconductor chips 150 may be smaller than that of the core layer 110. A process of mounting each of the semiconductor chips 150 on the substrate unit SU may include a thermal process. Since the core layer 110 and the semiconductor chip 150 have the CTEs different from each other, a warpage phenomenon may occur in the substrate regions SR during the thermal process. The substrate regions SR may be convexly warped upward or downward. Since the warpage control member 130 and the core layer 110 also have the CTEs different from each other, a warpage phenomenon may occur in the dummy regions DR during the thermal process. According to embodiments of the inventive concepts, a total warpage level of the substrate strip 100 may be controlled or adjusted by the warpage control members 130, as described below with reference to FIGS. 3A, 3B, 4A, and 4B.

The molding layer 160 may be provided on the top surface 110a of the core layer 110 to cover the semiconductor chips 150. The molding layer 160 may include, for example, epoxy molding compound.

The external connection solder balls 170 may be disposed on the external connection pads 122a of the second interconnection layer 122. A process of forming the external connection solder balls 170 may include a thermal process. A warpage phenomenon may occur in the substrate regions SR and the dummy regions DR by the thermal process.

As described above, the warpage control members 130 disposed on the bottom surfaces 110b of the dummy regions DR are described as an example for the purpose of ease and convenience in explanation. However, the inventive concepts are not limited thereto. In an embodiment, the warpage control members 130 may be disposed on the top surfaces 110a of the dummy regions DR. The warpage control members 130 may be formed along with the first interconnection layer 120 during a process of the first interconnection layer 120.

FIG. 4A is a cross-sectional view illustrating an example of a dummy region and a warpage control member deformed by a thermal process. FIG. 4B is a cross-sectional view illustrating a total warpage degree of a substrate strip relaxed using the deformation of the dummy region and the warpage control member illustrated in FIG. 4A.

Referring to FIG. 4A, the warpage control member 130 may be disposed on the bottom surface 110b of the dummy region DR of the core layer 110. When heat is applied to the core layer 110 and the warpage control member 130, the core layer 110 and the warpage control member 130 may be deformed. As described above, the CTE of the warpage control member 130 may be greater than that of the core layer 110. Thus, during the thermal process, the warpage control member 130 may be expanded more than the core layer 110, so the dummy region DR and the warpage control member 130 may be convexly warped in a facing direction of the bottom surface 110b of the core layer 110 (e.g., in a downward direction).

Referring to FIG. 4B, the core layer 110, the warpage control member 130, and the semiconductor chips 150 are simply illustrated. As described above, the substrate regions SR may be warped by the thermal process. In some embodiments, the substrate regions SR may be convexly warped in a facing direction of the top surface 110a of the core layer 110 (e.g., in an upward direction), as illustrated in FIG. 4B. In these embodiments, the warpage control member 130 may be disposed on the bottom surface 110b of the dummy region DR. In this case, the warpage control member 130 and the dummy region DR may be convexly warped in the facing direction of the bottom surface 110b of the core layer 110 by the thermal process, as described with reference to FIG. 4A. In other word, the direction in which the dummy region DR is warped may be opposite to the direction in which the substrate regions SR are warped, and thus, it is possible to relax a total warpage degree of the substrate strip 100 and the core layer 110 including the substrate regions SR warped in the facing direction of the top surface 110a of the core layer 110.

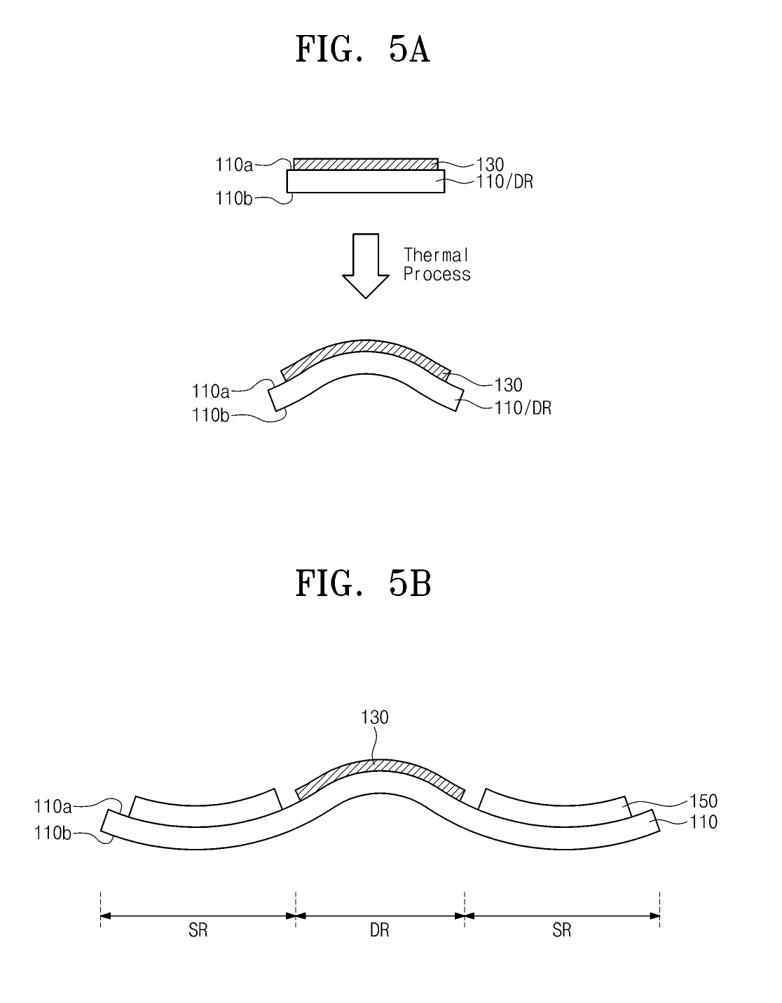

FIG. 5A is a cross-sectional view illustrating an example of a dummy region and a warpage control member deformed by a thermal process. FIG. 5B is a cross-sectional view illustrating a total warpage degree of a substrate strip relaxed using the deformation of the dummy region and the warpage control member illustrated in FIG. 5A.

Referring to FIG. 5A, the warpage control member 130 may be disposed on the top surface 110a of the dummy region DR of the core layer 110. When heat is applied to the core layer 110 and the warpage control member 130, the core layer 110 and the warpage control member 130 may be deformed. As described above, the CTE of the warpage control member 130 may be greater than that of the core layer 110. Thus, during the thermal process, the warpage control member 130 may be expanded more than the core layer 110, so the dummy region DR and the warpage control member 130 may be convexly warped in the facing direction of the top surface 110a of the core layer 110 (e.g., in the upward direction).

Referring to FIG. 5B, the core layer 110, the warpage control member 130 and the semiconductor chips 150 are simply illustrated. As described above, the substrate regions SR may be warped by the thermal process. In some embodiments, the substrate regions SR may be convexly warped in the facing direction of the bottom surface 110b of the core layer 110 (e.g., in the downward direction), as illustrated in FIG. 5B. In these embodiments, the warpage control member 130 may be disposed on the top surface 110a of the dummy region DR. In this case, the warpage control member 130 and the dummy region DR may be convexly warped in the facing direction of the top surface 110a of the core layer 110 by the thermal process, as described with reference to FIG. 5A. In other word, the direction in which the dummy region DR is warped may be opposite to the direction in which the substrate regions SR are warped, and thus, it is possible to relax a total warpage degree of the substrate strip 100 and the core layer 110 including the substrate regions SR warped in the facing direction of the bottom surface 110b of the core layer 110.

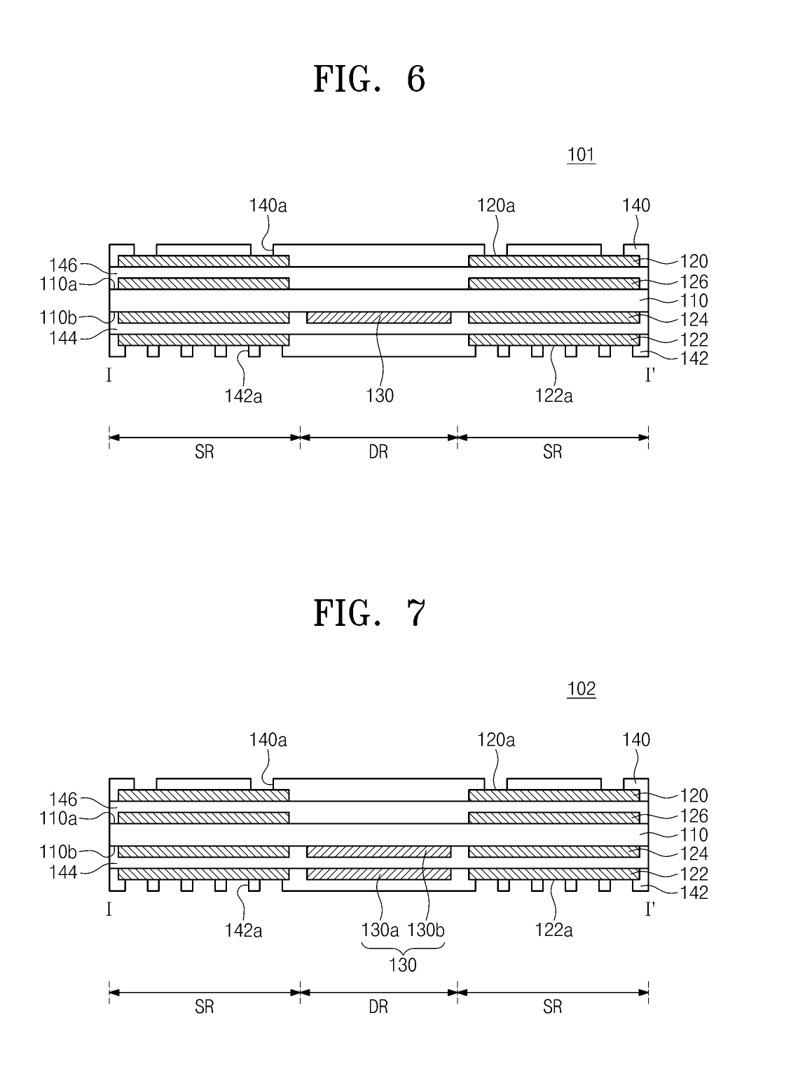

FIG. 6 is a cross-sectional view taken along the line I-I′ of FIG. 1A or 1B to illustrate a substrate strip according to an example embodiment of the inventive concepts. The same elements as described in the above embodiment will be indicated by the same reference numerals or the same reference designators, and the descriptions thereto will be omitted or mentioned briefly for the purpose of ease and convenience in explanation.

Referring to FIGS. 1A, 1B, and 6, a substrate strip 101 may further include a third interconnection layer 124, a fourth interconnection layer 126, a first insulating layer 144, and a second insulating layer 146 as well as the elements included in the substrate strip 101 of the example embodiment illustrated in FIG. 2.

The third interconnection layer 124 may be disposed between the second interconnection layer 122 and the substrate regions SR of the core layer 110. The first insulating layer 144 may be provided on the bottom surface 110b of the core layer 110 to cover the third interconnection layer 124. The fourth interconnection layer 126 may be disposed between the first interconnection layer 120 and the substrate regions SR. The second insulating layer 146 may be provided on the top surface 110a of the core layer 110 to cover the fourth interconnection layer 126. The third and fourth interconnection layers 124 and 126 may include, for example, a metal such as copper. The first and second insulating layers 144 and 146 may include an insulating material.

The warpage control members 130 may be disposed on the top surfaces 110a or the bottom surfaces 110b of the dummy regions DR. According to the example embodiment illustrated in FIG. 6, the warpage control members 130 may be disposed on the bottom surfaces 110b of the dummy regions DR. However, the inventive concepts are not limited thereto. In an embodiment, the warpage control members 130 may be disposed on the top surfaces 110a of the dummy regions DR.

The warpage control members 130 may be disposed at the same level as one of the first to fourth interconnection layers 120, 122, 124, and 126, relative to the core layer 110. According to the example embodiment illustrated in FIG. 6, the warpage control members 130 may be disposed at the same level as the third interconnection layer 124, relative to the core layer 110. However, the inventive concepts are not limited thereto. In an embodiment, the warpage control members 130 may be disposed at the same level as the second interconnection layer 122, relative to the core layer 110.

The warpage control members 130 may be spaced apart from the first to fourth interconnection layers 120, 122, 124, and 126 so as to be electrically insulated from the first to fourth interconnection layers 120, 122, 124, and 126.

The warpage control members 130 may have the CTE greater than that of the core layer 110. For example, the warpage control member 130 may include a metal such as copper.

As described with reference to FIGS. 4A, 4B, 5A, and SB, a total warpage degree of the substrate strip 101 according to the example embodiment illustrated in FIG. 6 may also be relaxed using deformation of the dummy region DR and the warpage control member 130.

FIG. 7 is a cross-sectional view taken along the line I-I′ of FIG. 1A or 1B to illustrate a substrate strip according to an example embodiment of the inventive concepts. The same elements as described in the above embodiments will be indicated by the same reference numerals or the same reference designators, and the descriptions thereto will be omitted or mentioned briefly for the purpose of ease and convenience in explanation.

Referring to FIGS. 1A, 1B, and 7, each of warpage control members 130 may include a first warpage control member 130a and a second warpage control member 130b. The warpage control members 130 may be disposed on the top surfaces 110a or the bottom surfaces 110b of the dummy regions DR. According to the example embodiment illustrated in FIG. 7, the warpage control members 130 may be disposed on the bottom surfaces 110b of the dummy regions DR. However, the inventive concepts are not limited thereto. In an embodiment, the warpage control members 130 may be disposed on the top surfaces 110a of the dummy regions DR.

As illustrated in FIG. 7, according to the example embodiment in which the warpage control members 130 are disposed on the bottom surfaces 110b of the dummy regions DR, the first warpage control member 130a may be disposed at the same level as the second interconnection layer 122, and the second warpage control member 130b may be disposed at the same level as the third interconnection layer 124.

Unlike FIG. 7, in an embodiment, the warpage control members 130 are disposed on the top surfaces 110a of the dummy regions DR, the first warpage control member 130a may be disposed at the same level as the first interconnection layer 120, and the second warpage control member 130b may be disposed at the same level as the fourth interconnection layer 126.

The first and second warpage control members 130a and 130b may be spaced apart from the first to fourth interconnection layers 120, 122, 124, and 126 so as to be electrically insulated from the first to fourth interconnection layers 120, 122, 124, and 126.

CTEs of the first and second warpage control members 130a and 130b may be greater than that of the core layer 110. For example, the first and second warpage control members 130a and 130b may include a metal such as copper.

As described with reference to FIGS. 4A, 4B, 5A, and 5B, a total warpage degree of a substrate strip 102 according to the example embodiment illustrated in f FIG. 7 may also be relaxed using deformation of the dummy region DR and the first and second warpage control members 130a and 130b.

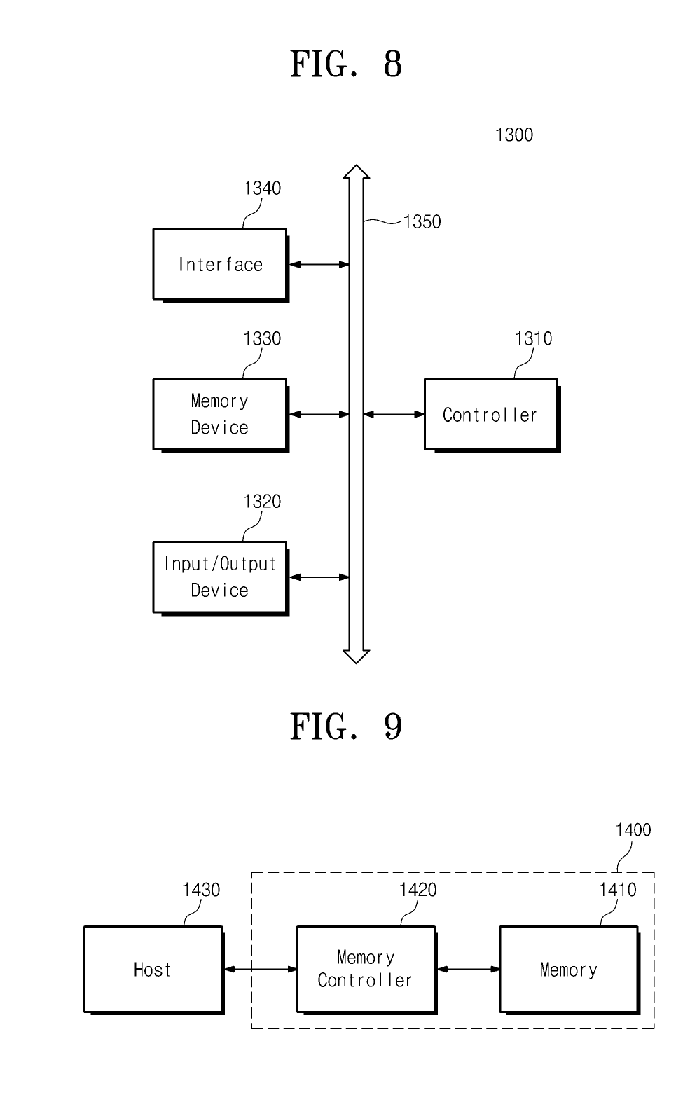

FIG. 8 is a schematic block diagram illustrating an example of an electronic system including a semiconductor package according to an example embodiment of the inventive concepts.

The semiconductor package may be produced by the above mentioned technique of the inventive concepts. The semiconductor package may be applied to an electronic system.

Referring to FIG. 8, an electronic device 1300 may include a controller 1310, an input/output (I/O) device 1320, and a memory device 1330. The controller 1310, the I/O device 1320, and the memory device 1330 may communicate with each other through a data bus 1350. The data bus 1350 may correspond to a path through which electrical data are transmitted. For example, the controller 1310 may include at least one of a microprocessor, a digital signal processor, a microcontroller, or another logic device having a similar function to any one thereof. At least one of the controller 1310 or the memory device 1330 may include at least one of the semiconductor packages according to the aforementioned embodiments of the inventive concepts. The I/O device 1320 may include at least one of a keypad, a keyboard, or a display device. The memory device 1330 may be a device storing data. The memory device 1330 may store data and/or commands executed by the controller 1310. The memory device 1330 may include a volatile memory device and/or a non-volatile memory device. Alternatively, the memory device 1330 may include a flash memory device. The flash memory device may be realized as a solid state disk (SSD). In this case, the electronic system 1300 may stably store massive data in the flash memory device. The electronic system 1300 may further include an interface unit 1340 which is used to transmit data to a communication network and/or to receive data from the communication network. The interface unit 1340 may be operated by wireless or cable. For example, the interface unit 1340 may include an antenna or a wireless/cable transceiver. The electronic system 1300 may further include an application chipset or a camera image processor (CIS).

The electronic system 1300 may be realized as a mobile system a personal computer, an industrial computer, or another logic system performing various functions. For example, the mobile system may be a personal digital assistant (PDA), a laptop computer, a portable computer, a web tablet, a wireless phone, a mobile phone, a digital music player, or a memory card, or a data transmitting/receiving system. When the electronic system 1300 performs wireless communication, the electronic system 1300 may be used in a communication interface protocol such as CDMA, GSM, NADC, E-TDMA, WCDMA, CDMA2000, Wi-Fi, Muni Wi-Fi, Bluetooth, DECT, Wireless USB, Flash-OFDM, IEEE 802.20, GPRS, iBurst, WiBro, WiMAX, WiMAX-Advanced, UMTS-TDD, HSPA, EVDO, LTE-Advanced, or MMDS.

FIG. 9 is a schematic block diagram illustrating an example of a memory card including a semiconductor package according to an example embodiment of the inventive concepts.

The semiconductor package may be produced by the above mentioned technique of the inventive concepts. The semiconductor package according to the inventive concepts may be used in a memory card. Referring to FIG. 9, a memory card 1400 may include a non-volatile memory device 1410 and a memory controller 1420. The non-volatile memory device 1410 and the memory controller 1420 may store data or may read out stored data. The non-volatile memory device 1410 may include at least one of non-volatile memory devices to which the semiconductor package technique according to the inventive concepts is applied. The memory controller 1420 may control the non-volatile memory device 1410 to read/write data from/into the non-volatile memory device 1410 in response to read/write requests of a host 1430.

The substrate strip according to sonic example embodiments of the inventive concepts may include the core layer including the substrate regions spaced apart from each other and the dummy region disposed between the substrate regions, and the warpage control member disposed on any one of the top surface and the bottom surface of the dummy region of the core layer. According to the inventive concepts, even though the substrate regions of the core layer are convexly warped by the thermal process, the dummy region of the core layer may be convexly warped in the direction opposite to the direction in which the substrate regions are warped. Thus, the total warpage degree of the core layer and the substrate strip may be relaxed.

While the inventive concepts have been described with reference to example embodiments, it will be apparent to those skilled in the art that various changes and modifications may be made without departing from the spirits and scopes of the inventive concepts. Therefore, it should be understood that the above embodiments are not limiting, but illustrative. Thus, the scopes of the inventive concepts are to be determined by the broadest permissible interpretation of the following claims and their equivalents, and shall not be restricted or limited by the foregoing description.

What is claimed is:

1. A substrate strip comprising:
a core layer including first and second substrate regions spaced apart from each other and a dummy region between the first and second substrate regions;
a first interconnection layer disposed on first surfaces of the first and second substrate regions;
a second interconnection layer disposed on second surfaces opposite to the first surfaces of the first and second substrate regions; and
a warpage control member provided on any one of a first surface and a second surface of the dummy region,
wherein the warpage control member includes a metal.

2. The substrate strip of claim 1, wherein the warpage control member includes copper.

3. The substrate strip of claim 1, wherein the warpage control member is in contact with the core layer.

4. The substrate strip of claim 1, wherein the warpage control member is electrically insulated from the first and second interconnection layers.

5. The substrate strip of claim 1, wherein the warpage control member includes a same material as the first interconnection layer or the second interconnection layer.

6. The substrate strip of claim 1, wherein
the warpage control member is provided on the second surface of the dummy region, and
the warpage control member is disposed at a same level as the second interconnection laver, relative to the core layer,

7. The substrate strip of claim 1, wherein
the core layer has a long axis extending in a first direction,
the first and second substrate regions are spaced apart from each other in the first direction, and
the dummy region extends in a second direction intersecting the first direction.

8. The substrate strip of claim 7, wherein the warpage control member has a rectangular shape extending in the second direction when viewed in plan view.

9. The substrate strip of claim 7, wherein the warpage control member includes segments spaced apart from each other and repeatedly arranged in the second direction when viewed in plan view.

10. The substrate strip of claim 1, further comprising:
a third interconnection layer disposed between the core layer and the second interconnection layer; and
a fourth interconnection layer disposed between the core layer and the first interconnection layer.

11. The substrate strip of claim 10, wherein the warpage control member is disposed at a same level as one of the first to fourth interconnection layers, relative to the core layer.

12. The substrate strip of claim 10, wherein
the warpage control member includes a first warpage control member and a second warpage control member,
the first warpage control member is disposed at a same level as the second interconnection layer, relative to the core layer, and
the second warpage control member is disposed at a same level as the third interconnection layer, relative to the core layer.

13. A substrate strip comprising:
a core layer including first and second substrate regions spaced apart from each other and a dummy region between the first and second substrate regions;
a first interconnection layer disposed on top surfaces of the first and second substrate regions;
a second interconnection layer disposed on bottom surfaces of the first and second substrate regions;
a warpage control member disposed on a bottom surface of the dummy region;
a first solder resist layer covering the first interconnection layer and a top surface of the dummy region, the first solder resist layer being in contact with the top surface of the dummy region; and
a second solder resist layer covering the second interconnection layer and the warpage control member.

14. The substrate strip of claim 13, wherein the warpage control member has a coefficient of thermal expansion (CTE) greater than that of the core layer.

15. The substrate strip of claim 14, wherein the warpage control member includes a metal.

16. The substrate strip of claim 13, wherein the warpage control member is disposed directly on the bottom surface of the dummy region.

17. The substrate strip of claim 13, wherein the warpage control member includes a same material as the second interconnection layer.

18. The substrate strip of claim 13, wherein the warpage control member is disposed at a same level as the second interconnection layer, relative to the core layer.

19. The substrate strip of claim 13, wherein
the first interconnection layer includes a chip bonding pad, and
the second interconnection layer includes an external connection pad.

20. A substrate strip comprising:
a core layer including a first surface and a second surface that is opposite to the first surface;
a first interconnection layer on the first surface of the core layer and including a first pad;
a second interconnection layer on the second surface of the core layer and including a second pad; and
a warpage control member on one of the first surface and the second surface of the core layer and separated from the first interconnection layer and the second interconnection layer;
wherein the warpage control member is positioned at a same level as the one of the first interconnection layer and the second interconnection layer, relative to the core layer, and is free of the first and second pads.
